(19) United States
(12) Patent Application Publication
(10) Pub. No.: US 2006/0180816 A1
(43) Pub. Date: Aug. 17, 2006

(54) Wide wavelength range silicon electroluminescence device

(75) Inventors: Tingkai Li, Vancouver, WA (US); Wei Gao, Vancouver, WA (US); Yoshi Ono, Camas, WA (US); Sheng Teng Hsu, Camas, WA (US)

Correspondence Address: SHARP LABORATORIES OF AMERICA, INC, 5750 NW PACIFIC RIM BLVD, CAMAS, WA, 98642, US

(73) Assignee: Sharp Laboratories of America, Inc.

(21) Appl. No.: 11/058,505

(22) Filed: Feb. 14, 2005

(51) Int. Cl. H01L 29/26

(52) U.S. Cl. 257/79

(57) ABSTRACT

A method is provided for forming a Si electroluminescence (EL) device for emitting light at short wavelengths. The method comprises: providing a substrate; forming a first insulator layer overlying the substrate; forming a silicon-rich silicon oxide (SRSO) layer overlying the first insulator layer, embedded with nanocrystalline Si having a size in the range of 0.5 to 5 nm; forming a second insulator layer overlying the SRSO layer; and, forming a top electrode. Typically, the SRSO has a Si richness in the range of 5 to 40%. In one aspect, the SRSO layer is formed using a DC sputtering process. In another aspect, the SRSO formation step includes a rapid thermal annealing (RTA) process subsequent to depositing the SRSO. Likewise, thermal oxidation or plasma oxidation can be performed subsequent to the SRSO layer deposition. The size of Si nanocrystals is decreased in response to above-mentioned deposition, annealing, and oxidation processes.

### BACKGROUND OF THE INVENTION

1. Field of the Invention

This invention generally relates to integrated circuit (IC) fabrication and, more particularly, to a silicon-based electroluminescence (EL) device that emits light in a wide band of wavelengths.

2. Description of the Related Art

The generation of light from semiconductor devices is possible, regardless of whether the semiconductor material forms a direct or indirect bandgap. High field reverse biased p-n junctions create large hot carrier populations that recombine with the release of photons. For silicon devices, the light generation efficiency is known to be poor and the photon energy is predominantly around 2 eV. The conversion of electrical energy to optical photonic energy is called electroluminescence (EL). Efficient EL devices have been made that can operate with small electrical signals, at room temperature. However, these devices are fabricated on materials that are typically not compatible with silicon, for example type III-V materials such as InGaN, AlGaAs, GaAsP, GaN, and GaP. An EL device built on one of these substrates can efficiently emit light in a narrow bandwidth within the visible region, depending on the specific material used. Additionally, type II-VI materials such as ZnSe have been used. Other type II-VI materials such as ZnS and ZnO are known to exhibit electroluminescence under ac bias conditions. These devices can be deposited onto silicon for use in light generating devices if special (non-conventional) CMOS processes are performed. Other classes of light emitting devices are organic light emitting diodes (OLEDs), nanocrystalline silicon (nc-Si), and polymer LEDs.

Silicon has conventionally been considered unsuitable for optoelectronic applications, due to the indirect nature of its energy band gap. Bulk silicon is indeed a highly inefficient light emitter. Among the different approaches developed to overcome this problem, quantum confinement in Si nanostructures and rare earth doping of crystalline silicon have received a great deal of attention. In particular, Si nanoclusters (nc) embedded in SiO₂ have in recent years attracted the interest of the scientific community as a promising new material for the fabrication of a visible Si-based light source. Alternatively, Er-doped crystalline Si has been extensively studied to take advantage of the radiative intra-4f shell Er transition. Room-temperature operating devices with efficiencies of around 0.05% have been achieved. The device efficiency is very low and the process temperature is very high, normally over 1100° C.

However, these pioneering efforts in creating visible luminescence emanating from porous room-temperature silicon (Si), have spurred a tremendous amount of research into using nano-sized Si to develop a Si-based light source. One widely used method of fabricating nanocluster Si (nc-Si) is to precipitate the nc-Si out of SiOx (where x<2), producing a film using chemical vapor deposition (CVD), radio frequency (RF)-sputtering, or Si implantation, which is often called silicon-rich silicon oxide (SRSO) or silicon-rich oxide (SRO). Using the CVD or RF-sputtering process, with a high-temperature annealing, a photoluminescence (PL) peak in the SRSO can be obtained in the wavelength range of 590 nanometers (nm) to 750 nm. No PL wavelengths below 590 nm have been reported. However, these SRSO materials exhibit low quantum efficiency and have a stability problem, which reduces the PL intensity height over time, and limits their application to EL devices.

Er implantation, creating Er-doped nanocrystal Si, is also used in Si-based light sources. However, state-of-the-art implantation processes have not been able to distribute the dopant uniformly, which lowers the light emitting efficiency and increases costs. At the same time, there has been no interface engineering sufficient to support the use of such a dopant. The device efficiency is very low and the process temperature is very high, which limits the device applications. In order to improve the device efficiency, a large interface area must be created between nanocrystal Si and SiO₂.

A simple and efficient light-emitting device compatible with silicon, and powered by a dc voltage would be desirable in applications where photonic devices (light emitting and light detecting) are necessary. Efficient silicon substrate EL devices would enable a faster and more reliable means of signal coupling, as compared with conventional metallization processes. Further, for intra-chip connections on large system-on-chip type of devices, the routing of signals by optical means is also desirable. For inter-chip communications, waveguides or direct optical coupling between separate silicon pieces would enable packaging without electrical contacts between chips. For miniature displays, a method for generating small point sources of visible light would enable simple, inexpensive displays to be formed.

It would be advantageous if a Si-based EL device could be fabricated that was stable enough to emit PL with a relatively constant intensity.

It would be advantageous if a stable Si-based EL device could be fabricated that emitted a broader spectrum of emitted light, especially in the lower wavelengths, below 590 nm.

### SUMMARY OF THE INVENTION

The present invention relates to the fabrication of EL and LED devices. The invention describes a method for controlling the grain size of nano crystal Si, and reducing the defects in Si-rich silicon dioxide materials for EL and LED device applications, using DC sputtering, thermal oxidation annealing, and plasma oxidation processes. Conventionally, the photoluminescence PL peak of SRSO materials is located in the wavelength range of 590 nm - 750 nm, and these SRSO materials exhibit a stability problem, which means that the PL peak height (intensity) decays over time, limiting their use in practical EL device applications. In order to increase the wavelength range, especially in the short wavelength range (below 590 nm), and improve stability, methods are disclosed herein to control the grain size of nano crystal Si, and reduce the defect density in SRSO materials. The SRSO film Si grain size can be controlled through DC sputtering, high-temperature annealing, thermal oxidation annealing, and plasma oxidation processes.

Accordingly, a method is provided for forming a Si EL device for emitting light at short wavelengths. Generally, the method comprises: providing a substrate; forming a first insulator layer overlying the substrate; forming a SRSO layer overlying the first insulator layer, embedded with nanocrystalline Si having a size in the range of 0.5 to 5 nm; forming a second insulator layer overlying the SRSO layer; and, forming a top electrode overlying the second insulator layer. Typically, the SRSO has a Si richness in the range of 5 to 40%, and the first and second insulator layers are a material such as SiO2, HfO2, or ZrO2, to name a few examples.

In one aspect, the SRSO layer is formed using a DC sputtering process. Smaller-sized Si nanocrystals are associated with reduced DC sputtering power levels. In another aspect, the SRSO formation step includes a rapid thermal annealing (RTA) process subsequent to depositing the SRSO. The size of Si nanocrystals can be made smaller in response to reducing the annealing temperature. Likewise, thermal oxidation or plasma oxidation can be performed subsequent to the SRSO layer deposition. Again, the size of Si nanocrystals is decreased in response to reducing the annealing temperatures associated with the oxidation processes.

Additional details of the above-described method, a method for generating short-wavelength light using a Si EL device, and a short-wavelength Si EL device are described below.

### BRIEF DESCRIPTION OF THE DRAWINGS

FIG. 1 is a partial cross-sectional view of a short-wavelength silicon (Si) electroluminescence (EL) device.

FIG. 2 is a partial cross-sectional view of a variation of the Si EL device of FIG. 1.

FIG. 3 is a depiction of a Si EL device structure.

FIG. 4 is a graph showing the Si richness in SRSO materials, at various DC sputtering powers, with an oxygen concentration of 15%.

FIGS. 5 and 6 are graphs depicting the grain size of nano Si crystal, responsive to varying DC sputtering powers and annealing temperatures, respectively.

FIG. 7 is a graph showing the PL spectrums of SRSO materials deposited at different DC powers, and annealed at a temperature of 1000° C. for 30 minutes.

FIG. 8 is a graph depicting the PL spectrums of SRSO samples taken before and after thermal oxidations.

FIG. 9 is a graph depicting the wavelength ranges of various SRSO materials using the present invention methods.

FIG. 10 is a graph depicting an SRSO material stability test.

FIG. 11 is a flowchart illustrating a method for forming a Si EL device for emitting light at short wavelengths.

FIG. 12 is a flowchart illustrating a method for generating short-wavelength light from a Si EL device.

### DETAILED DESCRIPTION

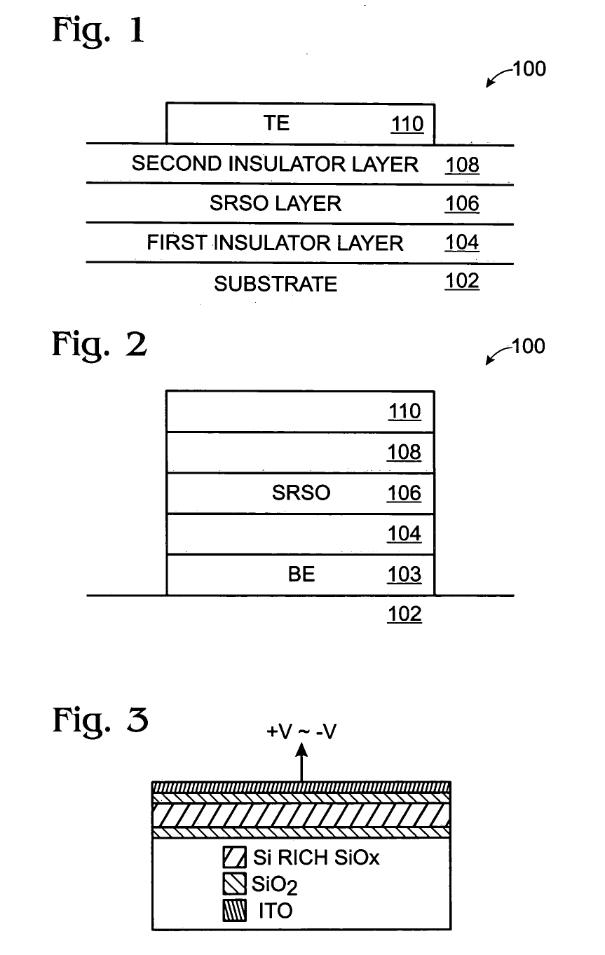

FIG. 1 is a partial cross-sectional view of a short-wavelength silicon (Si) electroluminescence (EL) device. The device 100 comprises a substrate 102, a first insulator layer 104 overlying the substrate 102, and a silicon-rich silicon oxide (SRSO) layer 106 overlying the first insulator layer 104. The SRSO layer 106 is embedded with nanocrystalline Si having a size in the range of 0.5 to 5 nm. Typically, the SRSO layer 106 has a Si richness in the range of 5 to 40%. A second insulator layer 108 overlies the SRSO layer 106 , and a top electrode 110 (TE) overlies the second insulator layer 108 .

Defects in the SRSO layer 106 occur as a result of impurities, non-uniformities, vacancies of Si or O, or porosity, to name a few possibilities. Using processes discussed below, impurities can be reduced and improvements made in uniformity, as compared to a conventional implantation process. For example, after thermal annealing, the vacancies of Si or O can be reduced, and the porosity of the SRSO film can be improved from 10%, to a number in the range of 0 to 5%.

The substrate 102 can be a material such as Si, N type Si, P type Si, gallium arsenic (GaAs), silicon carbide (SiC), gallium nitride (GaN), or Al2O3 (sapphire), or temperature-sensitive materials such as Si glass, quartz, or plastic. The first insulator layer 104 and the second insulator layer 108 can be a material such as SiO2, HfO2, ZrO2, Ai2O3, La2O3, Si3N4, TiO2, Ta2O5, or Nb2O5. Note, the first insulator layer 104 need not be the same material as the second insulator layer 108 . Typically, the top electrode 110 is a transparent material such as indium tin oxide (ITO), zinc oxide (ZnO), or thin metals such as gold (Au), aluminum (Al), or chromium (Cr).

FIG. 2 is a partial cross-sectional view of a variation of the Si EL device of FIG. 1. In this aspect, the top electrode 110 need not be transparent. In addition to the transparent materials mentioned above, the top electrode 110 can a material such as polycrystalline Si, Pt, Ir, Al, AlCu, Au, Ag, YBCO, ITO, RuO₂, or La₁₋ₓSrₓCoO₃. In this aspect, a bottom electrode 103 (BE) is interposed between the substrate 102 and the first insulator layer 104 . If the top electrode 110 is transparent, then the bottom electrode 102 is typically a non-transparent material such as poly-Si, Pt, Ir, Al, AlCu, Au, Ag, YBCO, ITO, RuO₂, or La₁₋ₓSrₓCoO₃. Alternately, if the substrate 102 is transparent, the bottom electrode 103 can be made from a transparent material such as ITO, Au, Al, ZnO, or Cr. As another alternative, a non-transparent top electrode 110 can be used, and light can be emitted through the second insulator layer 108, interposed between the SRSO layer 106 and the top electrode 110.

### Functional Description

Quantum Confinement Effect in Si Nanometer-Scale-Crystallites

Silicon nanocrystals with diameters of less that 5 nm exhibit room temperature visible photoluminescence PL. Increases in the emitted photon energy can be obtained by decreasing Si nanocrystal diameters down to less than 1 nm, due to the recombination of quantum-confined excitons. The PL spectra generated from Si nanocrystals in SRSO materials is in the range of 500 to 900 nm, depending on the grain size of Si nanocrystals.

Surface or Interface Effects of Si Nanometer-Scale-Crystallites

For SRSO materials, it is believed that the photoemission comes from the Si—SiO₂ interface, specifically from the silicon-to-oxygen double bond (Si═O). Therefore, improving the total area and quality of the Si—SiO₂ interface is a very important issue.

The Presence of Defects in SRSO Materials Reduces the PL Intensity

Base on the above studies, it is possible to increase the wavelength range, especially for short wavelength range, increase the PL intensity, and solve the decay problem. These issues are addressed by increasing the interface area of Si/SiO₂, controlling the grain size of Si nanocrystal to around 0.5-5 nm, and reducing the defects within the Si nanocrystals and Si/SiO₂ interface.

A method has been developed to control the grain size of nano crystal Si, and reduce the defects density in SRSO materials. In one aspect, the film is deposited by DC sputtering, and followed by high-temperature anneal. The crystal size of Si nano particles can be controlled through thermal oxidation, annealing, or plasma oxidation. Using these methods, SRSO materials have been made with PL wavelength in the range from 500 nm to 800 nm. These SRSO materials have a high PL intensity, with a significantly improved stability

FIG. 3 is a depiction of a Si EL device structure. The EL device can be made with various grain size of nano crystal Si in SRSO, all with low defect density. The DC-sputtering processes, rapid thermal annealing (RTA), thermal oxidation, and plasma oxidation processes used to accomplish this are shown in Tables 1 2, 3 and 4, respectively.

TABLE 1
Si-rich Si dioxide DC sputtering process conditions

| | | Deposition | Deposition | | Deposition |
|---|---|---|---|---|---|
| Target | Power | temp. | pressure | Atmosphere | time |
| Si | 100-300 | 20-300° | 2-10 | Ar or N2 | Depending |
| | | C. | mTorr | with | on |
| | | | | 2-30% O₂ | required |
| | | | | | thickness |

TABLE 2
Si-rich Si dioxide RTF thermal annealing process conditions

| Rapid thermal | Annealing | | |
|---|---|---|---|
| rates (° C./s) | temperature | Atmosphere | Annealing time |
| 50-500 | 800-1200° C. | Ar or N2 | 5-60 minutes |

TABLE 3
Si-rich Si dioxide thermal oxidation conditions

| Annealing | | |
|---|---|---|
| temperature | Atmosphere | Annealing time |
| 800-1200° C. | Ar or N2 with | 5-60 minutes |
| | 2-30% O₂ | |

TABLE 4
Si-rich Si dioxide plasma oxidation conditions

| | Pressure | | | Oxidation |
|---|---|---|---|---|
| Power (w) | (torr) | Temperature | Atmosphere | time |
| | | 250° C. | 4-5% O₂ | 1-20 |
| | | | | minutes |

Experimental results show that the PL and EL wavelengths of Si-rich silicon oxide depend on the grain size of nano Si crystals. In response to reducing the grain size of nano Si crystals, the Si-rich silicon oxides shift to shorter wavelengths. Conventionally, SRSO materials emit PL in the wavelength range from 590 nm to 750 nm, and no reports are known of SRSO materials emitting wavelengths below 590 nm. In order to make SRSO materials having wider range of wavelength, high PL intensity, and good stability, the nano Si grain size and size distribution must be controlled, to increase density (Si richness) of Si nano particles, and to reduce defects in SRSO materials. The following methods are used to obtain these results.

1). Using various DC sputtering powers and oxygen partial pressures to control the Si richness in SRSO materials.

2). Using various annealing temperatures and oxygen partial pressures, including without oxygen, to control the grain size of Si nano crystal in SRSO materials.

3). Using thermal oxidation and plasma oxidation to adjust the grain size of Si nano crystals in the SRSO materials.

4). Using high-temperature annealing, and thermal or plasma oxidation to reduce the defects in SRSO materials.

5) Optimizing the above-mentioned methods to select the appropriate Si richness and grain size, and to obtain the maximum number of Si nano particles in the SRSO materials.

6) Repeating and combining the above-mentioned methods.

For example, high Si richness SRSO materials can by deposited by high DC sputtering power with low oxygen partial pressure, and then thermal annealed and oxidized at an appropriate temperature and oxygen partial pressure. In this way, an SRSO material with the desired wavelength, high efficiency and good stability can be made. On the other hand, low Si richness SRSO materials can be deposited using a low DC sputtering power, with low or high oxygen partial pressure, and then thermal annealed at high temperature.

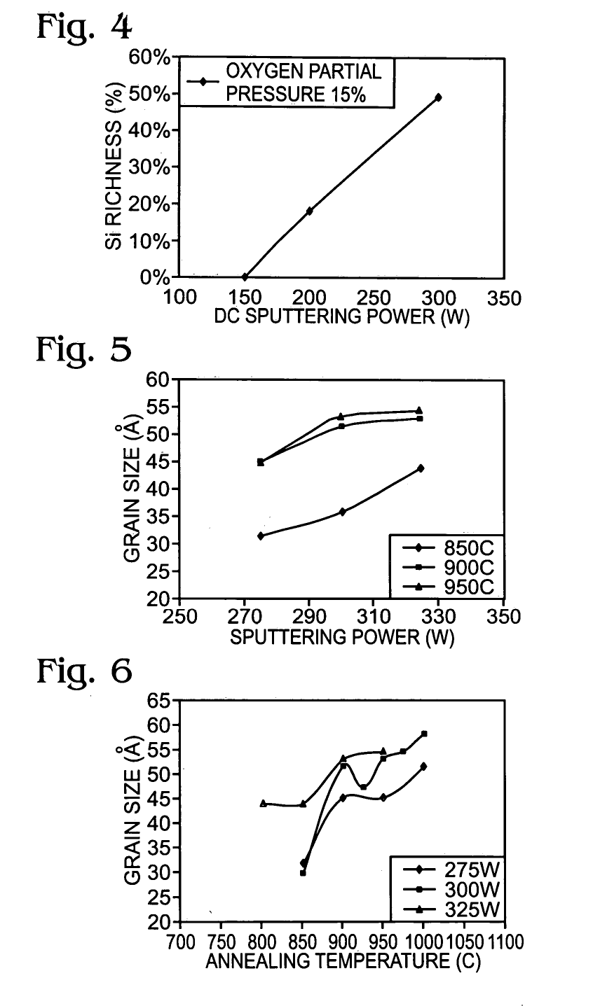

FIG. 4 is a graph showing the Si richness in SRSO materials, at various DC sputtering powers, with an oxygen concentration of 15%. From the figure it can be seen that the Si richness in SRSO materials increases from 0% to 49%, by increasing DC sputtering power from 150 watts (W) to 300 W, holding the oxygen partial pressure 15%. Using different DC sputtering powers and oxygen partial pressures, various Si rich nesses can be formed in the SRSO materials.

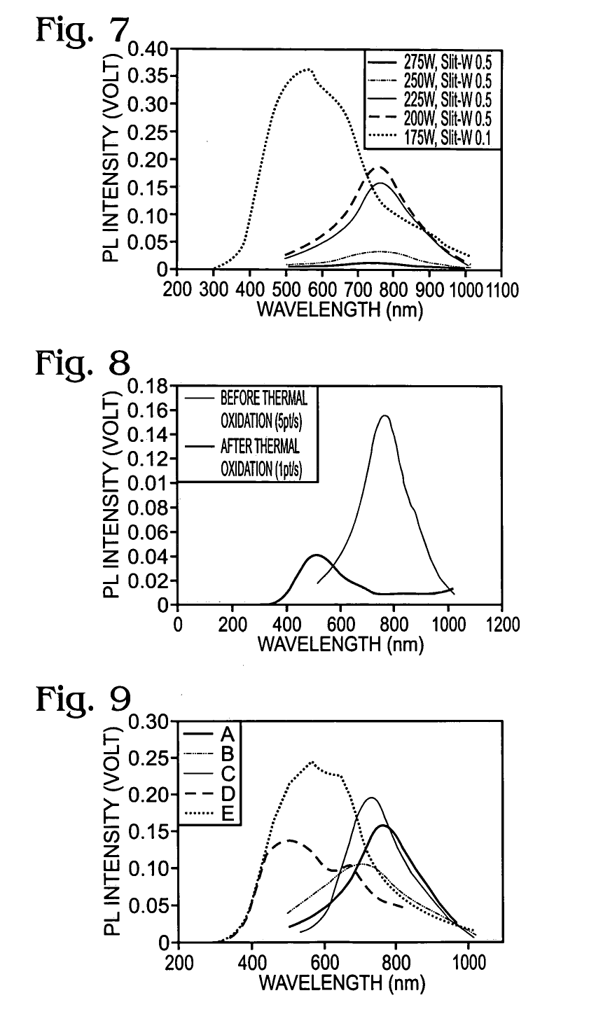

FIGS. 5 and 6 are graphs depicting the grain size of nano Si crystal, responsive to varying DC sputtering powers and annealing temperatures, respectively. Selecting different DC sputtering powers and annealing temperatures, various grain sizes of nano Si crystals can be obtained. From FIG. 5, the grain size of nano Si crystals decreases from 4.4 nm to 3.1 nm, by decreasing the DC plasma power from 325 W to 275 W, at annealing temperature of 850° C. for 30 minutes. If the DC sputtering power is continuously reduced, the grain size of nano Si crystals is further decreased. At a fixed DC sputtering power of 300 W, the grain size of nano Si crystals increases from 2.9 nm to 5.8 nm, in response to increasing the annealing temperature from 850° C. to 1000° C. for 30 minutes (FIG. 6). Using these methods, the various grain sizes of nano Si crystals in SRSO materials can be obtained.

FIG. 7 is a graph showing the PL spectrums of SRSO materials deposited at different DC powers, and annealed at a temperature of 1000° C. for 30 minutes. The EL and PL intensity depend upon the density of Si nano particles and particle size. PL intensities increase with decreasing DC sputtering power due to the formation of Si nano particles with grain size of 3-1 nm. If the grain size of Si nanocrystals decreases significantly, the PL wavelength shifts to a short wavelength range. The SRSO sample made with a DC sputtering power of 175 W shows that the PL wavelength is shifted down to 500 nm. However, post-thermal oxidation or plasma oxidation can also be used to reduce the grain size of nano Si crystals in SRSO materials, to shift the PL wavelength to a shorter wavelength range.

FIG. 8 is a graph depicting the PL spectrums of SRSO samples taken before and after thermal oxidations. From the figure it can be seen that the PL wavelength shifts from 780 nm to 500 nm, with reduced PL intensity after thermal oxidation, which is a likely result of decreasing the numbers of nano particles in the SRSO material.

FIG. 9 is a graph depicting the wavelength ranges of various SRSO materials using the present invention methods. Using the above-mentioned methods, various grain sizes of nano Si crystals in SRSO materials have been formed, resulting in wide PL wavelength ranges from 500 nm to 800 nm.

FIG. 10 is a graph depicting an SRSO material stability test. Very stable PL properties are exhibited in SRSO materials with 10% Si richness, which have been annealed at 950° C., in Ar, for 30 minutes. Likewise the SRSO material is very stable if annealed at 1000° C., in Ar, for 30 minutes, and then further annealed at 1050° C. in a lesser oxygen atmosphere for 30 minutes. As seen, appropriate thermal annealing and oxidation processes can reduce the defect density in SRSO materials. Therefore, SRSO materials with close to zero degradation in PL properties can be made. Stable SRSO materials have the characteristic of emitting a relatively constant PL intensity, even as the SRSO material ages.

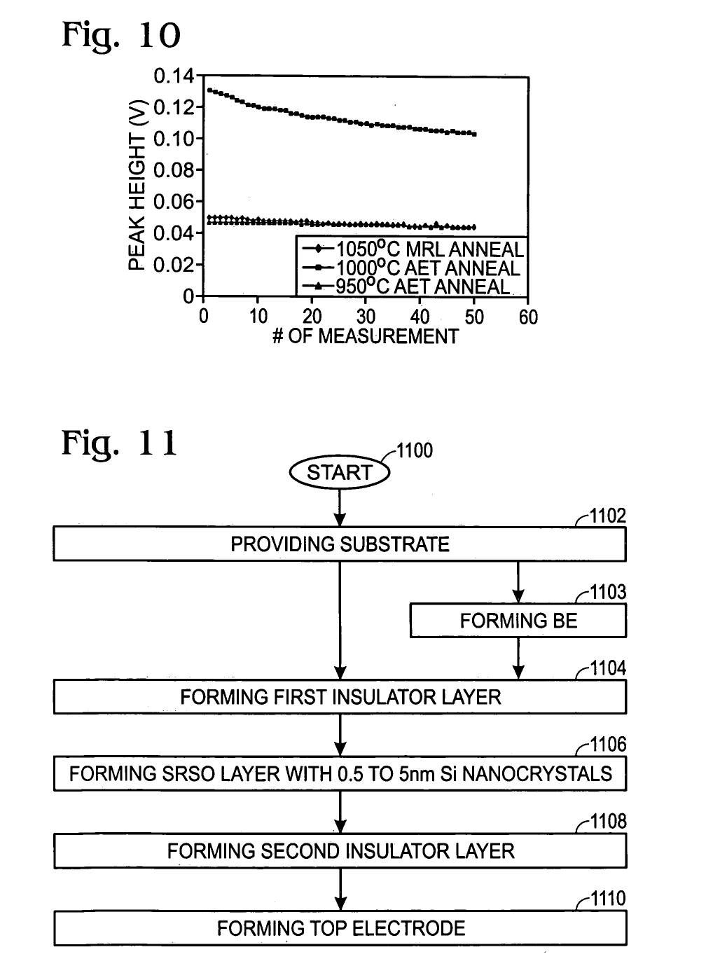

FIG. 11 is a flowchart illustrating a method for forming a Si EL device for emitting light at short wavelengths. Although the method is depicted as a sequence of numbered steps for clarity, no order should be inferred from the numbering unless explicitly stated. It should be understood that some of these steps may be skipped, performed in parallel, or performed without the requirement of maintaining a strict order of sequence. The method starts at Step 1100.

Step 1102 provides a substrate. Step 1104 forms a first insulator layer overlying the substrate. Step 1106 forms a SRSO layer overlying the first insulator layer, embedded with nanocrystalline Si having a size in the range of 0.5 to 5 nm. Typically, Step 1106 forms a SRSO layer with a Si richness in the range of 5 to 40%. Step 1108 forms a second insulator layer overlying the SRSO layer. Step 1110 forms a top electrode overlying the second insulator layer.

In one aspect, forming the SRSO layer in Step 1106 includes DC sputtering the SRSO layer on the first insulator layer. Typically, the size of Si nanocrystals decreases in response to reducing the DC sputtering power. For example, the DC sputtering substeps may include:

using a Si target;

applying power within the range of 100 to 300 W;

heating the substrate to a temperature in the range of 20 to 300° C.,

using a deposition pressure in the range of 2 to 10 mTorr; and

supplying an atmosphere including 2 to 30% O2, with a gas such as Ar or N2.

In another aspect, Step 1106 performs a rapid thermal annealing (RTA) process subsequent to depositing the SRSO. Typically, the size of Si nanocrystals decreases in response to reducing the annealing temperature. For example, the RTA process may include the substeps of:

using a rapid thermal rate in the range of 50° C. to 500° C./second;

heating the substrate to a temperature in the range of 800 to 1200° C.;

supplying an atmosphere such as Ar or N2; and

annealing for a duration in the range between 5 and 60 minutes.

In a different aspect, Step 1106 thermally oxidizes the SRSO layer subsequent to deposition. Typically, the size of Si nanocrystals decreases in response to reducing the annealing temperature. For example, thermally oxidizing the SRSO layer may include the substeps of:

heating the substrate to a temperature in the range of 800 to 1200° C.;

supplying an atmosphere including 2 to 30% O2, with a gas such as Ar or N2; and

annealing for a duration in the range between 5 and 60 minutes.

In another aspect, Step 1106 plasma oxidizes the SRSO layer subsequent to deposition. Typically, the size of Si nanocrystals decreases in response to reducing the annealing temperature. For example, Step 1106 may plasma oxidize the SRSO layer as follows:

heating the substrate to a temperature of approximately 250° C.;

supplying an atmosphere including 4 to 5% O2; and

oxidizing for a duration in the range of 1 to 20 minutes.

In one aspect, providing a substrate in Step 1102 includes using a material such as Si, N type Si, P type Si, Si glass, gallium arsenic (GaAs), silicon carbide (SiC), gallium nitride (GaN), Al2O3 (sapphire), or temperature-sensitive materials such as Si glass, quartz, and plastic.

In some aspects the substrate acts as the bottom electrode. Alternately, Step 1103 forms a bottom electrode interposed between the substrate and the first insulator layer. The bottom electrode may be formed from a material such as polycrystalline Si, Pt, Ir, Al, AlCu, Au, Ag, YBCO, ITO, RuO₂, or La₁₋ₓSrₓCoO₃. Alternately, Step 1103 forms a transparent bottom electrode from a material such as indium tin oxide (ITO), gold (Au), aluminum (Al), zinc oxide (ZnO), or chromium (Cr). If the bottom electrode is transparent, then the substrate formed in Step 1102 may also be transparent.

In one aspect, Step 1110 a top electrode from a transparent material such as ITO, Au, Al, ZnO, or Cr. Alternately, the top electrode may be a non-transparent material such as polycrystalline Si, Pt, Ir, Al, AlCu, Au, Ag, YBCO, ITO, RuO₂, or La₁₋ₓSrₓCoO₃.

In a different aspect, forming the first and second insulator layers in Step 1104 and 1108, respectively, includes forming first and second insulator layers from a material such as SiO2, HfO2, ZrO2, Ai2O3, La2O3, Si3N4, TiO2, Ta2O5, or Nb2O5.

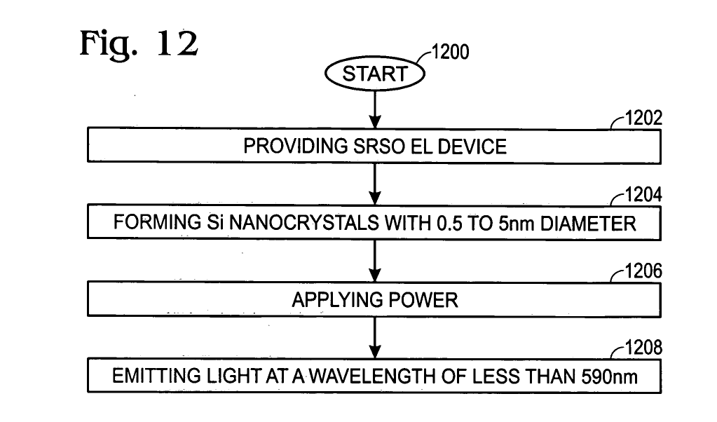

FIG. 12 is a flowchart illustrating a method for generating short-wavelength light from a Si EL device. The method starts at Step 1200. Step 1202 provides an EL device including a substrate, a first insulator layer overlying the substrate, a SRSO layer overlying the first insulator layer, a second insulator layer overlying the SRSO layer, and a top electrode overlying the second insulator layer. Step 1204 forms nanocrystalline Si in the SRSO having a size in the range of 0.5 to 5 nm. Typically, Step 1204 forms a SRSO layer with a Si richness in the range of 5 to 40%. Step 1206 applies power to the EL device. In one aspect, Step 1206 applies a DC pulse having an amplitude of 120 volts, or greater. Step 1208 emits light having a wavelength of less than 590 nanometers (nm). In one aspect, Step 1208 emits light with wavelengths in the range of 500 to 800 nm. In another aspect, Step 1208 emits light with a decay in intensity of less that 5%, after more that 50 cycles of applied power.

In one aspect, forming nanocrystalline Si in Step 1204 includes DC sputtering the SRSO layer on the first insulator layer. In another aspect, Step 1204 performs a rapid thermal annealing (RTA) process subsequent to depositing the SRSO. In a different aspect, Step 1204 thermally oxidizes the SRSO layer subsequent to deposition. In one other aspect, Step 1204 plasma oxidizes the SRSO layer subsequent to deposition.

A SRSO material EL device and a fabrication process have been providing for making such as device with small diameter Si nanocrystals. A few examples of specific materials, environmental conditions, and temperatures have been given to illustrate the invention. However, the invention is not limited to merely these examples. Other variations and embodiments will occur to those skilled in the art.

We claim:

1. A method for forming a silicon (Si) electroluminescence (EL) device for emitting light at short wavelengths, the method comprising:
providing a substrate;
forming a first insulator layer overlying the substrate;
forming a silicon-rich silicon oxide (SRSO) layer overlying the first insulator layer, where SRSO is a silicon oxide embedded with nanocrystailine Si, having a stoichiometric composition of SiOx (x<2) and a predominate nanocrystalline Si grain size within the range of 0.5 to 5 nm;
forming a second insulator layer overlying the SRSO layer; and
forming a top electrode overlying the second insulator layer.

2. The method of claim 1 wherein forming the SRSO layer includes forming a SRSO layer with a Si richness in the range of 5 to 40%.

3. The method of claim 1 wherein forming the SRSO layer includes DC sputtering the SRSO layer on the first insulator layer.

4. The method of claim 3 wherein DC sputtering the SRSO layer includes:
using a Si target;
heating the substrate to a temperature in the range of 20 to 300° C.,
using a deposition pressure in the range of 2 to 10 mTorr; and
supplying an atmosphere including 2 to 30% O2, with a gas selected from the group including Ax and N2.

5. The method of claim 3 wherein forming the SRSO layer includes decreasing the size of Si nanocrystals in response to reducing the DC sputtering power.

6. The method of claim 1 wherein forming the SRSO layer includes performing a rapid thermal annealing (RTA) process subsequent to depositing the SRSO.

7. The method of claim 6 wherein performing the RTA process includes:
using a rapid thermal rate in the range of 50° C. to 500° C./second;
heating the substrate to a temperature in the range of 800 to 1200° C.;
supplying an atmosphere selected from the group including Ar and N2; and
annealing for a duration in the range between 5 and 60 minutes.

8. The method of claim 7 wherein forming the SRSO layer includes decreasing the size of Si nanocrystals in response to reducing the annealing temperature.

9. The method of claim 1 wherein forming the SRSO layer includes thermally oxidizing the SRSO layer subsequent to deposition.

10. The method of claim 9 wherein thermally oxidizing the SRSO layer includes:
heating the substrate to a temperature in the range of 800 to 1200° C.;
supplying an atmosphere including 2 to 30% O2, with a gas selected from the group including Ar and N2; and
annealing for a duration in the range between 5 and 60 minutes.

11. The method of claim 9 wherein forming the SRSO layer includes decreasing the size of Si nanocrystals in response to reducing the annealing temperature.

12. The method of claim 1 wherein forming the SRSO layer includes plasma oxidizing the SRSO layer subsequent to deposition.

13. The method of claim 12 wherein plasma oxidizing the SRSO layer includes:
heating the substrate to a temperature of approximately 250° C.;
supplying an atmosphere including 4 to 5% O2; and
oxidizing for a duration in the range of 1 to 20 minutes.

14. The method of claim 12 wherein forming the SRSO layer includes decreasing the size of Si nanocrystals in response to reducing the annealing temperature.

15. The method of claim 1 wherein providing a substrate includes providing a substrate material selected from the group including Si, N type Si, P type Si, Si glass, gallium arsenic (GaAs), silicon carbide (SiC), gallium nitride (GaN), Al2O3 (sapphire), and temperature-sensitive material selected from the group including glass, plastic, and quartz.

16. The method of claim 1 further comprising:
forming a bottom electrode interposed between the substrate and the first insulator layer.

17. The method of claim 16 wherein forming the bottom electrode includes forming the bottom electrode from a material selected from the group of polycrystalline Si, indium tin oxide (ITO), gold (Au), aluminum (Al), zinc oxide (ZnO), and chromium (Cr), Pt, Ir, Al, AlCu, Au, Ag, YBCO, ITO, RuO₂, and La₁₋ₓSrₓCoO₃.

18. The method of claim 1 wherein forming a top electrode includes forming a top electrode from a material selected from the group including polycrystalline Si, ITO, Au, Al, ZnO, Cr, Pt, Ir, Al, AlCu, Au, Ag, YBCO, ITO, RuO₂, and La₁₋ₓSrₓCoO₃.

19. The method of claim 1 wherein forming the first and second insulator layers includes forming first and second insulator layers from a material selected from the group of SiO2, HfO2, ZrO2, Ai2O3, La2O3, Si3N4, TiO2, Ta2O5, and Nb2O5.

20. A method for generating short-wavelength light from a silicoxl (Si) electroluminescence (EL) device, the method comprising:
providing an EL device including a substrate, a first insulator layer overlying the substrate, a silicon-rich silicon oxide (SRSO) layer overlying the first insulator layer, where SRSO is a silicon oxide embedded with nanocrystalline Si, having a stoichiometric composition of SiOx (x<2) and a predominate nanocrystalline Si grain size within the range of 0.5 to 6 nm, a second insulator layer overlying the SRSO layer, and a top electrode overlying the second insulator layer;
applying power to the EL device; and
emitting light having a wavelength of less than 590 nanometers (nm).

21. The method of claim 20 wherein emitting light includes emitting light with wavelengths in the range of 500 to 800 nm.

22. The method of claim 20 wherein forming nanocrystalline Si includes forming a SRSO layer with a Si richness in the range of 5 to 40%.

23. The method of claim 20 wherein forming nanocrystalline Si includes DC sputtering the SRSO layer on the first insulator layer.

24. The method of claim 20 wherein forming nanocrystalline Si includes performing a rapid thermal annealing (RTA) process subsequent to depositing the SRSO.

25. The method of claim 20 wherein forming nanocrystalline Si includes thermally oxidizing the SRSO layer subsequent to deposition.

26. The method of claim 20 wherein forming nanocrystailine Si includes plasma on oxidizing the SRSO layer subsequent to deposition.

27. The method of claim 20 wherein applying power includes applying a DC pulse having an amplitude of 120 volts, or greater.

28. The method of claim 20 wherein emitting light includes emitting light with a decay in intensity of less that 5%, after more that 50 cycles of applied power.

29. A short-wavelength silicon (Si) electroluminescence (EL) device, the device comprising:
a substrate;
a first insulator layer overlying the substrate;
a silicon-rich silicon oxide (SRSO) layer overlying the first insulator layer, where SRSO is a silicon oxide embedded with nanocrystalline Si, having a stoichiometric composition of SiOx (x<2) and a predominate nanocrystalline Si grain size within the range of 0.5 to 5 nm;
a second insulator layer overlying the SRSO layer; and
a top electrode overlying the second insulator layer.

30. The device of claim 29 wherein the SRSO layer has a Si richness in the range of 5 to 40%.

31. The device of claim 29 wherein the substrate is a material selected from the group including Si, N type Si, P type Si, Si glass, gallium arsenic (GaAs), silicon carbide (SiC), gallium nitride (GaN), and Al2O3 (sapphire), and temperature-sensitive material selected from the group including glass, plastic, and quartz.

32. The device of claim 29 further comprising:
a bottom electrode interposed between the substrate and the first insulator layer.

33. The device of claim 32 wherein the bottom electrode is a material selected from the group of polycrystalline Si, indium tin oxide (ITO), gold (Au), aluminum (Al), zinc oxide (ZnO), and chromium (Cr), Pt, Ir, Al, AlCu, Au, Ag, YBCO, ITO, RuO₂, and La₁₋ₓSrₓCoO₃.

34. The method of claim 32 wherein the substrate is transparent material; and,
wherein the bottom electrode is a transparent material.

35. The device of claim 29 wherein the first and second insulator layers are a material selected from the group of SiO2, HfO2, ZrO2, Ai2O3, La2O3, Si3N4, TiO2, Ta2O5, and Nb2O5.

36. The device of claim 29 wherein the top electrode is a material selected from the group including polycrystalline Si, ITO, Au, Al, ZnO, Cr, Pt, Ir, Al, AlCu, Au, Ag, YBCO, ITO, RuO₂, and La₁₋ₓSrₓCoO₃.

37. The device of claim 29 wherein the SRSO layer has a porosity in the range of 0 to 5%.
